(19) United States
(12) Patent Application Publication
(10) Pub. No.: US 2004/0036541 A1
(43) Pub. Date: Feb. 26, 2004

(54) Differential CMOS latch and digital quadrature LO generator using same

(76) Inventors: Sher Jiun Fang, Seattle, WA (US); See Taur Lee, Seattle, WA (US); Abdellatif Bellaouar, Dallas, TX (US)

Correspondence Address: TEXAS INSTRUMENTS INCORPORATED, P O BOX 655474, M/S 3999, DALLAS, TX, 75265

(21) Appl. No.: 10/227,937

(22) Filed: Aug. 26, 2002

(51) Int. Cl. H03B 1/00; H03B 27/00

(52) U.S. Cl. 331/74; 438/57

(57) ABSTRACT

A wideband digital quadrature local oscillator (LO) generator (300) using clocked-CMOS (C²MOS) latches (302, 304) can operate at very high frequencies, while consuming less current and having lower phase noise as compared to prior art quadrature LO generators using Source-coupled logic (SCL) latches. In addition, the LO generator (300) has no low frequency limit and can output rail-to-rail square waves.

### TECHNICAL FIELD

This invention relates in general to the field of electronic circuits, and more specifically to a differential Complementary Metal Oxide Semiconductor (CMOS) latch and a digital quadrature generator using the CMOS latch.

### BACKGROUND

Quadrature Local Oscillator (LO) signal generators are important building blocks in digital wireless communication systems. They are used for example in, quadrature modulators, demodulators and image rejection mixers. A conventional quadrature LO generator is shown in FIG. 1. Several techniques for generating IP (In-phase) and QP (Quadrature-phase) LO signals exist, with the most commonly used technique for generating a pair of quadrature LO signals requiring the use of divide-by 2 circuits. An example of a conventional Source Coupled Logic (SCL) latch is shown in FIG. 2.

Conventional quadrature Local Oscillator LO signal generators use SCL latches for generating the In-Phase and Quadrature-Phase LO signals. Such LO signal generators have low operating frequency limits, and they do not provide rail-to-rail (i.e., square wave) output signals, which are recommended, for RF CMOS mixers and other circuits. LO generators incorporating SCL latches also suffer from high noise and also consume a large amount of power. SCL latches also need to be followed by a source follower or driver before the signal is sent to the next stage, thereby increasing power consumption. A need thus exist in the art for a new latch and digital quadrature LO generator using this new latch which can provide power consumption improvements and avoid the low-frequency limits of prior art quadrature signal generators.

### BRIEF DESCRIPTION OF THE DRAWINGS

The features of the present invention, which are believed to be novel, are set forth with particularity in the appended claims. The invention, may best be understood by reference to the following description, taken in conjunction with the accompanying drawings, in the several figures of which like reference numerals identify like elements, and in which:

FIG. 1 shows a block diagram of a prior art Quadrature LO generator using SCL latches.

FIG. 2 shows a schematic of a prior art SCL latch.

FIG. 3 shows a block diagram of a digital quadrature LO generator using CMOS latches in accordance with one embodiment of the present invention.

FIG. 4 shows a schematic of a Clocked CMOS latch in accordance with the invention.

FIG. 5 shows an output waveform for the digital quadrature LO generator of FIG. 3.

FIG. 6 is a detailed schematic of the back-to-back inverter section found in FIG. 4.

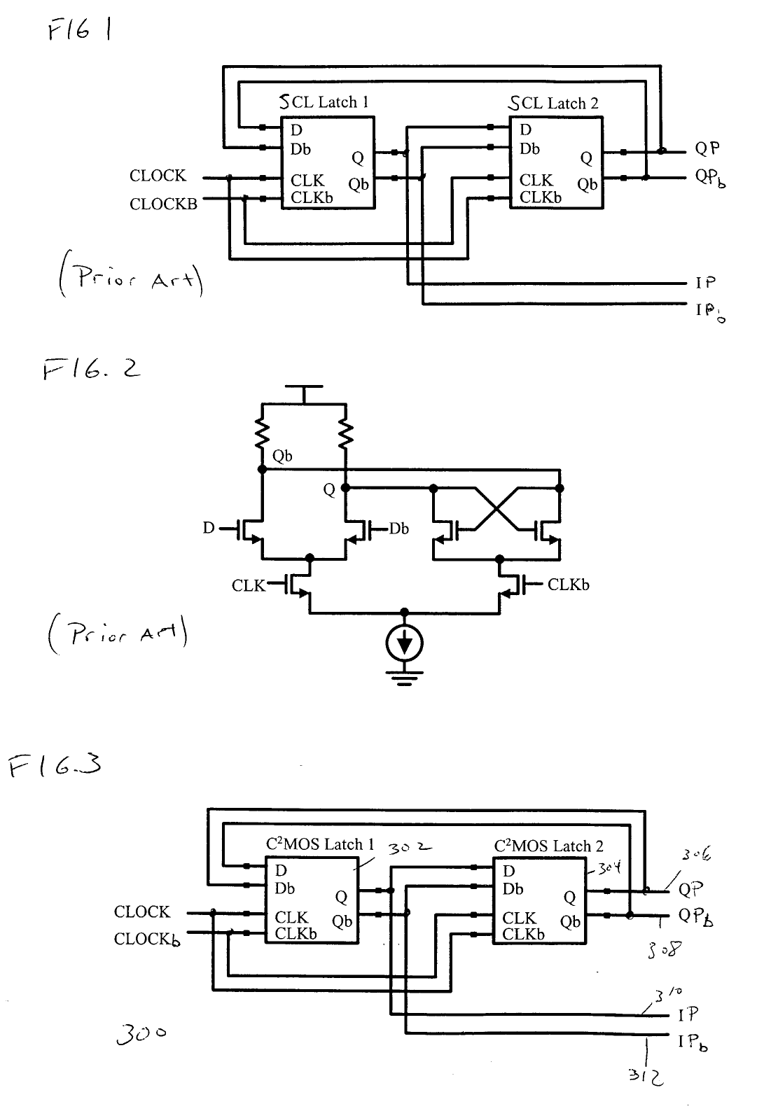

### DETAILED DESCRIPTION OF THE PREFERRED EMBODIMENT

While the specification concludes with claims defining the features of the invention that are regarded as novel, it is believed that the invention will be better understood from a consideration of the following description in conjunction with the drawing figures.

Referring now to FIG. 3, there is shown a digital quadrature LO generator 300 in accordance with the preferred embodiment of the invention. Generator 300 includes two Clocked CMOS (also referred herein as C²MOS) latches 302 and 304, which are triggered by the positive and negative edges of an input clock. A clock signal input port (CLK) and a complementary clock signal input port (CLKb, referring to CLK bar) are provided as part of each latch 302 and 304. When the clock signal (CLOCK) presented to the CLK input port is a logic high, the clock signal (CLOCKb) presented to the CLKb port is a logic low and vice-versa. Since the quadrature generator 300 is a divide-by-2 circuit, the input frequency is twice the output frequency. Each latch 302 and 304 includes a pair of differential input ports D and Db and a pair of differential output ports Q and Qb. The latches 302 and 304 are connected together as shown in FIG. 3 in order to provide In-phase (IP 310 and IPb 312) and Quadrature-phase (QP 306 and QPb 308) output signals.

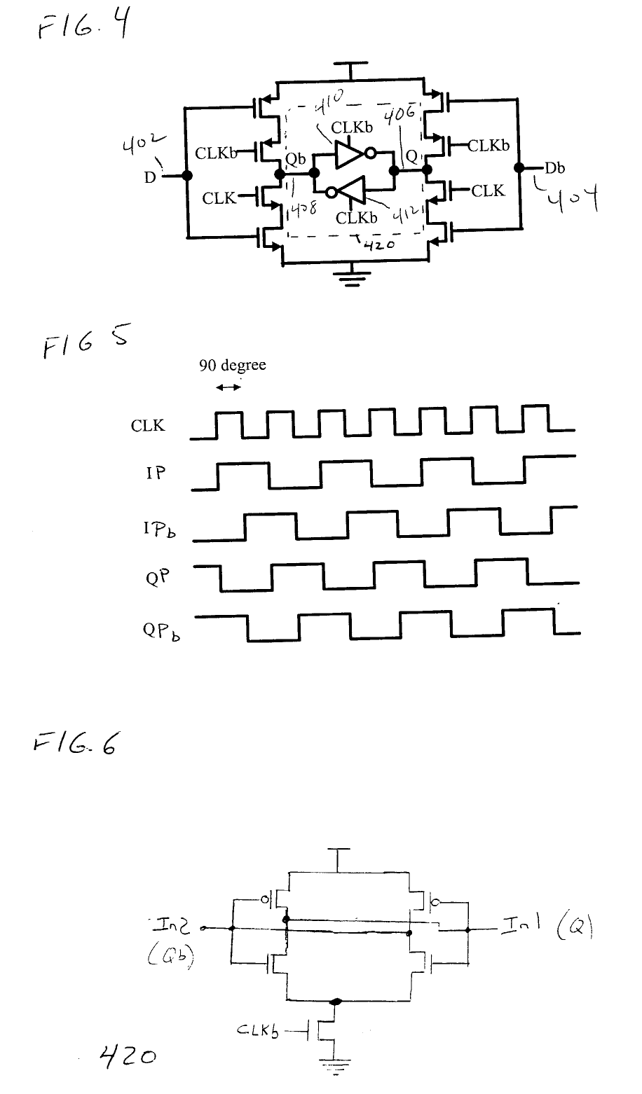

In FIG. 4 there is shown a differential C²MOS latch 400 that can be used for latches 302 and 304 of LO generator 300 in accordance with the invention. This positive level sensitive latch passes the signals present at the D 402 and Db 404 input ports to the Q 406 and Qb 408 output ports when the clock signal (CLOCK) presented to the CLK clock input port is a logic high. When the CLOCK signal is a logic low, the input data is sampled on the falling edge of the CLOCK signal, and is held stable at the LO gnerator's output ports (QP 306, QPb 308) for the entire phase due to the back-to-back inverter 410, 412 connections found in each latch 302, 304. The back-to-back inverter section 420 is shown in schematic detail in FIG. 6.

When two of these latches 300 are connected in a master-slave configuration as done in the LO generator 300, one latch 302 acts as a positive latch and the other latch 304 acts as a negative latch. With the negative output (Qb) of the second latch 304 feedback to the positive input (D) of the first latch 302, it will generate In-Phase and Quadrature-Phase signals at half the frequency of the input clock signal. The output waveforms for digital quadrature LO generator 300 is shown in FIG. 5. Note that the performance of generator 300 is power supply dependent.

A simulation at 2 GHz input frequency and using a 1.5 volt power supply, yielded a power consumption of 259 μA for quadrature LO generator 300. The phase noise at different relative offset frequencies is tabulated in Table 1 below. Quadrature LO generator 300 has the advantage of having no low frequency limit.

TABLE 1

| Offset Frequency | Phase Noise |
|---|---|
| 5 MHz | −150.25 dBc/Hz |
| 10 MHz | −151.86 dBc/Hz |
| 20 MHz | −153.0 dBc/Hz |

While the preferred embodiments of the invention have been illustrated and described, it will be clear that the invention is not so limited. Numerous modifications, changes, variations, substitutions and equivalents will occur to those skilled in the art without departing from the spirit and scope of the present invention as defined by the appended claims.

What is claimed is:

1. A differential Clocked-CMOS (C²MOS) latch, comprising:
first (CLK) and second (CLKb) clock input ports for receiving complementary clock signals (CLOCK and CLOCKb);
first and second input ports (D and Db);
first and second output ports (Q and Qb); and
a pair of back-to-back inverters coupled between the first and second output ports.

2. A differential C₂MOS latch as defined in claim 1, wherein the differential C₂MOS latch is a positive level latch that passes signals present at the first and second input ports to the first and second output ports in response to the first (CLK) complementary clock input port receiving a logic high level clock signal.

3. A differential C²MOS latch as defined in claim 1, wherein any signals present at the first and second input ports are sampled in response to the first (CLK) complementary clock input port receiving a falling edge clock signal and any signals present at the first and second input ports are held stable at the first and second output ports in response to the first (CLK) complementary clock input port receiving a logic low level clock signal.

4. A differential C²MOS latch as defined in claim 1, further comprising:
a voltage source input port;
a ground port;
first, second, third and fourth transistors coupled together and connected between
the voltage source input port and the ground port;
the first and fourth transistors connected to the first differential output port (D);
the second transistor connected to the second clock input port (CLKb); and
the third transistor connected to the first clock input port (CLK).

5. A differential C²MOS latch as defined in claim 4, wherein the second and third transistors are directly connected to the second output port (Qb).

6. A differential C²MOS latch as defined in claim 5, further comprising:
fifth, sixth, seventh and eighth coupled between the voltage source input port and the ground port.

7. A differential C²MOS latch as defined in claim 6, wherein:
the fifth and eighth transistors are connected to the second differential output port (Db);
the sixth transistor is connected to the second clock input port (CLKb); and
the seventh transistor connected to the first clock input port (CLK).

8. A differential C²MOS latch as defined in claim 7, wherein the sixth and seventh transistors are directly connected to the first output port (Q)

9. A quadrature Local Oscillator (LO) generator, comprising:
a first differential Clocked-CMOS (C²MOS) latch; and
a second differential C²MOS latch coupled to the first differential C²MOS latch.

10. A quadrature LO generator of claim 9, wherein
the first and second differential C²MOS latches are coupled together in order to provide a pair of In-phase (IP and IPb) and pair of Quadrature-phase (QP and QPb) output ports.

11. A quadrature LO generator as defined in claim 9, wherein the first and second C²MOS latches are coupled together in a master-slave relationship.

12. A quadrature LO generator as defined in claim 10, wherein the first C²MOS latch acts as a positive latch and the second C²MOS latch acts as a negative latch.

13. A quadrature LO generator as defined in claim 9, wherein each of the first and second C²MOS latches comprise:
first (D) and second (Db) input ports;
first (Q) and second (Qb) output ports; and
back-to-back inverters coupled between the first (Q) and second (Qb) output ports.

14. A quadrature LO generator as defined in claim 13, wherein the first output port (Q) of the first latch is coupled to the first input port (D) of the second C²MOS latch and the second output port (Qb) of the first latch is coupled to the second input port (Db) of the second latch; and
the first and second output ports of the first C²MOS latch provide the In-phase output ports (IP, IPb) for the quadrature LO generator, while the first and second output ports of the second C²MOS latch provide the quadrature-phase output ports (QP, QPb) for the quadrature LO generator.
